(19) United States
(12) Patent Application Publication
(10) Pub. No.: US 2024/0421243 A1
(43) Pub. Date: Dec. 19, 2024

(54) METHOD FOR PRODUCING A TRENCH IN A III-V MULTI-JUNCTION SOLAR CELL

(71) Applicant: AZUR SPACE Solar Power GmbH, Heilbronn (DE)

(72) Inventors: Steffen SOMMER, Tamm (DE); Wolfgang KOESTLER, Heilbronn (DE)

(73) Assignee: AZUR SPACE Solar Power GmbH, Heilbronn (DE)

(21) Appl. No.: 18/744,483

(22) Filed: Jun. 14, 2024

(30) Foreign Application Priority Data
Jun. 14, 2023 (DE) 10 2023 002 414.7

(51) Int. Cl. H01L 31/18; H01L 31/0304

(52) U.S. Cl. CPC H01L 31/184; H01L 31/0304

(57) ABSTRACT

A method for producing a trench-shaped structure in a III-V multi-junction solar cell with an upper side and an underside. The III-V multi-junction solar cell includes a substrate arranged on the underside, and the substrate has an epilayer system on a front side. The epilayer system has at least one first III-V solar cell formed on the upper side, an organic layer is arranged on the first solar cell, and in a first processing step a first trench with a width X is created via a laser. In a second processing step a second trench with a width Y and with a bottom surface formed in the substrate is created via the laser, wherein the width Y is smaller than the width X, so that a first step is formed with the execution of the second processing step.

This nonprovisional application claims priority under 35 U.S.C. § 119 (a) to German Patent Application No. 10 2023 002 414.7, which was filed in Germany on Jun. 14, 2023, and which is herein incorporated by reference.

### BACKGROUND OF THE INVENTION

### Field of the Invention

The present invention relates to a method for producing a trench in a III-V multi-junction solar cell.

### Description of the Background Art

A laser cutting process for producing through holes for vias in GaAs or Ge solar cells is known from DE 692 16 502 T2, which corresponds to U.S. Pat. No. 5,425,816, wherein the disclosed process is intended, among other things, to avoid the disadvantages of a CVD SiO₂ coating for through holes.

In the conventional art, it is known that in a first process step, a through opening with a large diameter is created by means of laser pulses from a solid-state laser. In order to prepare the very rough surfaces, arising during laser bombardment, on the side walls of the through opening for subsequent metallization, the side walls, among others, are covered with a polyimide in a second process step or, in the case of smaller through openings, the opening is completely filled with polyimide.

In a subsequent process step, the polyimide is heated to cure. The polyimide is referred to as a dielectric coating.

In a fourth process step, a through hole with a small diameter is created within the polyimide using the laser, wherein the polyimide has a smooth surface on the newly created side surfaces after laser bombardment. The polyimide side surfaces are covered with a metal in a subsequent process step.

It is known in the conventional art that the need to smooth the side surfaces by means of aggressive chemical etching is also avoided by the application of polyimide and protects the active area of the solar cell and the GaAs substrate or the Ge substrate from the etching attack. Further, the polyimide has good adhesion both to the substrate and to a through-hole metallization to be applied.

### SUMMARY OF THE INVENTION

It is therefore an object of the invention is to provide a method by which the conventional art is refined.

According to the subject matter, a method for producing a trench in a III-V multi-junction solar cell is provided.

The III-V multi-junction solar cell has an upper side and an underside and comprises a substrate arranged on the underside.

The substrate is formed as a semiconductor wafer and has an epilayer system with a plurality of III-V layers on a front side.

The epilayer system comprises at least one first III-V solar cell formed on the upper side of the III-V multi-junction solar cell, wherein an organic layer is arranged on the first III-V solar cell.

In a first processing step, a first trench with a width X and with a bottom surface formed in the epilayer system is created by means of a laser.

In a second processing step, a second trench with a width Y and with a bottom surface formed in the substrate is created in the bottom surface of the first trench by means of the laser, wherein the width Y is smaller than the width X, so that a first step is formed with the execution of the second processing step.

The aforementioned processing steps can be carried out in the specified sequence or, for example, the second processing step can be carried out before the first processing step, wherein the second trench is created before the first trench in the example.

The organic layer can comprise a coating layer and/or a polyimide layer and/or a plastic layer. It is understood that the layers are unstructured, in particular to avoid a masking step, i.e., a lithography step.

The substrate can be a semiconductor substrate with a diameter of at least or exactly 100 mm or at least or exactly 150 mm.

The term dielectric layer may exclusively cover inorganic layers, in particular oxide and nitride layers.

Furthermore, it should be noted that the term “trench” can refer to an elongated depression with a length of at least 100 μm or at least 200 μm.

It is understood that the term “epilayer system” can refer exclusively to the III-V layers produced on the substrate by means of an epitaxy process.

Furthermore, it should be noted that the side surfaces resulting in all laser-based processing steps are formed exactly vertical or almost vertical, wherein the term “almost vertical” can be understood to mean a deviation of less than 5°.

The opening angle can be less than 20° or less than 10°. The opening angle can be understood to be the angle that is inclined to the vertical, wherein the inclination is “outwards” so that the total angle is more than 90°. In other words, the trench has a larger diameter at the upper side than at the bottom region in a non-vertical design; therefore, it is formed conical; the trench has a conical shape in cross section.

An advantage is that the organic layers, especially coating layers, allow continuous trenches to be flexibly arranged anywhere on the upper side of the III-V multi-junction solar cell by the method without further structuring using complex and expensive lithography processes.

A further advantage is that the at least two-step laser process is surprisingly insensitive to a nonessential change in the layer structure, in particular the thickness and number of Ill-V layers. The method is also insensitive to the change in substrate material from Ge to GaAs and vice versa.

Nonessential changes are in particular a change in the III-V material composition and the stoichiometry and a change in the total layer thickness of less than 20 μm.

Another advantage is that even with an essential change in the substrate thickness, the setting of the laser can be easily changed in laser-based processing steps.

In the present case, an essential change can be defined as a change in the thickness of the substrate by at least 50 μm or at least 100 μm.

Another advantage of laser-based processing steps compared to wet-chemical processing steps is that no underetching occurs. Furthermore, wet-chemical processing steps generally require a structured application of protective coatings on the top surface and/or side surfaces of trench-shaped structures, especially if the trench-shaped structure comprises at least one step.

In a third processing step, a slot can be created in the bottom of the second trench along the trench-shaped structure starting from the upper side or starting from the underside by means of a separation process in order to divide the substrate. In a refinement, the slot has at least a length of 50 μm. The two processing steps, i.e., the first processing step and the second processing step, may have already been carried out.

The slot can be formed continuously along a straight line and can be created with a width Z, wherein the width Z lies in a range between 5 μm and 120 μm or between 10 μm and 80 μm.

In the third processing step, the substrate can be divided by means of a saw starting from the underside of the III-V multi-junction solar cell or from the underside of the substrate.

The third processing step for creating the slot can be carried out using the laser starting from the upper side of the III-V multi-junction solar cell. It is understood here that the laser-based processing step is preferably carried out immediately after the other two laser-based processing steps.

In other words, the third processing step can be carried out, for example, by means of a laser process starting from the upper side or starting from the underside of the substrate by means of a saw. The further side surfaces resulting during the execution of the third processing step in the slots are also formed almost vertical or exactly vertical.

Furthermore, it should be noted that the bottom surface formed in the epilayer system in the first trench can comprise a second trench, wherein the bottom surface of the second trench is formed in the substrate. Accordingly, the bottom surface of the first trench can be divided into two parts by the second trench, wherein the two parts of the bottom surface of the first trench each run along the side surfaces made of III-V material.

If the second trench comprises a slot extending to the underside of the substrate, the bottom surface of the second trench can also be divided into two parts, namely, by the slot, wherein the two parts of the bottom surface of the second trench each run along the side surfaces formed from the material of the substrate.

The surfaces formed in the bottom areas can be flat or are flat to a first approximation or have uneven surfaces and that the surface on the bottom consists exclusively of a III-V material in the case of the epilayer system or exclusively of the substrate material in the case of the bottom surface in the substrate.

If the processing steps are not carried out in the specified order, in an example, the second processing step can be carried out first and then either the first processing step or the third processing step is carried out. After this, the processing step that has not yet been carried out, i.e., the third processing step or the first processing step, can be carried out.

It is understood that after all three processing steps have been carried out, regardless of the order of their execution, at least one first step is always formed or, in the case of forming the slot, two steps are formed.

In other words, even if the processing steps are carried out in different sequences or the third processing step is carried out in different ways, the resulting step shapes correspond to one another in a cross-sectional view or, in particular, are formed substantially or exactly the same.

The first two processing steps, i.e., the first processing step and the second processing step, can be carried out one after the other without intermediate steps, such as wet etching steps or dry etching steps.

The third laser processing step or all laser-based processing steps can be carried out one after the other without intermediate steps, in particular such as wet etching steps or dry etching steps.

In an example, instead of the three successive laser processing steps, more than three, for example, four or five, processing steps can also be carried out using the laser.

In a refinement, at least one further III-V solar cell can be formed between the substrate and the first III-V solar cell.

The first III-V solar cell as the uppermost III-V solar cell can have a larger band gap or a band gap of the same size as the III-V solar cells below it.

A plurality of tunnel diode layers can be arranged between the two III-V solar cells in order to electrically connect the stacked III-V solar cells together in series.

The two III-V solar cells can have the same or different materials. The uppermost III-V solar cell can comprise an InGaP compound. In a refinement, the further III-V solar cell is formed as a second III-V solar cell and comprises a GaAs compound or an InGaAs compound.

The substrate can comprise Ge or GaAs or consists of Ge or GaAs. It is understood that a plurality of III-V layers are arranged on the substrate. Preferably, the layers are epitaxially grown using a MOVPE system.

A substrate solar cell can be formed in the upper side of the substrate or on the upper side of the substrate. In the case of the GaAs substrate, the substrate solar cell can be a III-V solar cell, in the case of Ge, a VI solar cell.

It should be noted that when the substrate is formed as a Ge substrate, the Ge substrate is usually formed as a p-Ge substrate and in the case of the formation of an n-Ge layer for the formation of the group VI solar cell on the top surface or in the top surface of the p-Ge substrate, the n-layer is created by means of diffusion of dopants and not by means of epitaxy.

The substrate can have a thickness in a range between 40 μm and 850 μm. In another refinement, the thickness of the substrate is within a range between 150 μm and 750 μm.

Further layers can be formed above the first III-V solar cell and below the organic layer, wherein the further layers are formed as organic and/or inorganic layers. Preferably, the further layers, passivation layers, comprise or consist of, for example, at least one III-V layer and/or at least one silicon oxide layer and/or at least one silicon nitride layer.

An antireflection layer can be formed between the first III-V solar cell and the organic layer.

The organic layer can be formed as a continuous layer covering the entire upper side of the first III-V solar cell, i.e., unstructured. In this case, the organic layer can be applied either by spin coating or by another coating process.

A metal layer can be arranged on the upper side of the III-V multi-junction solar cell in the area of the trench between the first III-V solar cell and the organic layer, or no metal layer is formed at all. In other words, when a metal layer is formed or not formed at the location of the trench to be produced, the first processing step and/or the second processing step can be carried out.

At least one second step can be formed in the trench in a direction from the upper side to the underside of the III-V multi-junction solar cell during the execution of the laser process.

After the execution of the first two processing steps with the laser, a wet chemical etching can be carried out, in particular to clean the top surfaces and the side surfaces.

Depending on the etching solution used and its application time, only one of the two steps is still visible after the etching. The wet-chemical etching step can be carried out immediately after the execution of the second laser processing step or after the execution of the first laser-based processing step and the second laser-based processing step.

In the wet etching step, the width of the first trench and the width of the second trench can each be increased and/or the depth of the first trench and/or of the second trench can be increased. In a refinement, the enlargement of the first trench and/or the second trench can be in a range between 0.5 μm and 30 μm.

The removal of the organic layer can be carried out only after the execution of a wet-chemical etching step. An advantage is that the top surface is protected from an etching attack by the organic layer.

The width X of the first trench can be in a range between 20 μm and 300 μm. The width Y of the second trench can be in a range between 5 μm and 200 μm. It is understood, however, that the width of the first trench is always wider than the width of the second trench. Alternatively, the ratio of the width of the first trench to the width of the second trench lies in a range between 1 and 10.

A wet etching step can be carried out after the execution of all laser-based processing steps. An advantage of the wet etching step is that the surfaces are cleaned of residues from the laser-based processing steps.

The wet etching step can be carried out before the sawing step.

A wet etching step can be carried out immediately after the second processing step or after the first two processing steps have been carried out, i.e., before the removal of the organic layer. An advantage is that, via the organic layer, the upper side or top surface of the multi-junction solar cell is protected not only from contamination during the laser-based processing steps, but also from an etching attack.

The organic layer may only be removed after all laser-based processing steps and the wet etching step have been carried out. It should be noted that the organic layer is preferably removed by means of a wet chemical or dry etching process.

The substrate can be formed as a semiconductor wafer with a diameter of at least or exactly 100 mm or at least or exactly 150 mm.

The substrate may only be divided along the trench.

The third processing step may not be carried out in predetermined areas, so that the second bottom is retained and the substrate is not divided in the predetermined areas.

### BRIEF DESCRIPTION OF THE DRAWINGS

The present invention will become more fully understood from the detailed description given hereinbelow and the accompanying drawings which are given by way of illustration only, and thus, are not limitive of the present invention, and wherein:

FIGS. 1a to 1c are cross-sectional views of a resulting trench structure after different laser processing steps;

FIG. 2 is a cross-sectional view of the trench structure of the example shown in FIG. 1c after a wet etching step and coating removal process;

FIG. 3 is a cross-sectional view of the trench structure with a slot after a third laser-based processing step;

FIG. 4 is a cross-sectional view of the trench structure with a slot after a sawing step; and

FIG. 5 shows a top plan view of a semiconductor wafer with trench structure and slot.

### DETAILED DESCRIPTION

The cross sections shown below each show a section of a multi-junction solar cell structure MS, wherein the multi-cell structure MS or a plurality of multi-cell structures is or are formed on a semiconductor wafer with a diameter of at least 100 mm.

The following illustrations also show exclusively one embodiment in which processing steps one to three are carried out in the order indicated; i.e., the first processing step is carried out first, the second processing step second, and, if the third processing step is carried out, the third processing step is carried out after the second processing step.

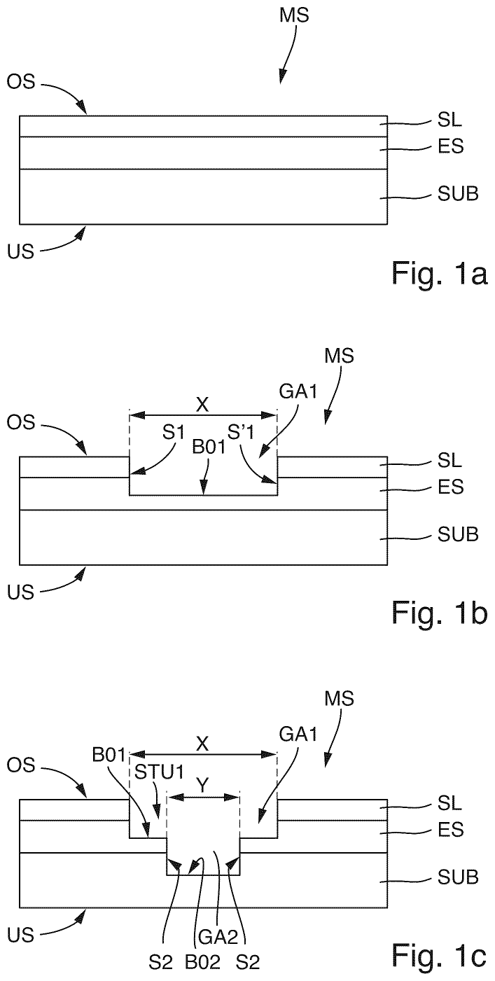

The illustration in FIGS. 1a to 1c shows individual cross-sectional views of a resulting trench structure, wherein the illustration of FIG. 1b shows the resulting trench structure after the execution of the first laser processing step and the illustration of FIG. 1c shows the resulting trench structure after the execution of the second laser processing step.

The illustration in FIG. 1a shows a cross-sectional view of an unprocessed multi-junction solar cell structure MS with an underside US and an upper side OS. A substrate layer SUB made of germanium or GaAs is formed on the underside US of the multi-junction solar cell structure MS. The substrate layer SUB has an underside, wherein the underside of the substrate layer SUB is formed on the underside US of the multi-cell structure MS.

An epilayer system ES is formed on an upper side of substrate layer SUB. The epilayer system ES is integrally bonded to substrate layer SUB. It is understood that the epilayer system ES comprises a plurality of III-V layers.

The epilayer system ES comprises at least one first solar cell (not shown), wherein the first solar cell is always formed as the uppermost solar cell, even if one or more further solar cells are formed between the first solar cell and substrate SUB in further embodiments which are not shown.

An organic layer SL in the form of a protective coating is arranged on epilayer system ES. In the embodiment shown, organic layer SL is integrally bonded over the entire surface to the upper side of the III-V epilayer system ES on the semiconductor wafer.

In an embodiment which is not shown, a further layer or further layers, in particular passivation layers, are formed integrally bonded to the epilayer system ES between the epilayer system and organic layer SL.

In a first processing step, shown in FIG. 1b, a first trench GA1 with an opening having a width X is created by means of a laser through the organic layer SL with a first bottom surface BO1 formed in epilayer system ES. The resulting side surfaces S1 are formed almost vertical.

In a second processing step, shown in FIG. 1c, an opening with a width Y and with a second bottom surface BO2 formed in substrate SUB is created in bottom surface BO1 of first trench GA1 by means of the laser, wherein the width Y is smaller than the width X. By creating a second trench GA2 in only part of first bottom surface BO1 of the epilayer system, a first step STU1 is created. Side surfaces S2 resulting in the second processing step are also formed almost vertical.

It is understood that in an embodiment which is not shown, the processing steps carried out by means of the laser are also carried out in a different sequence. In particular, the second processing step can be carried out before the first processing step.

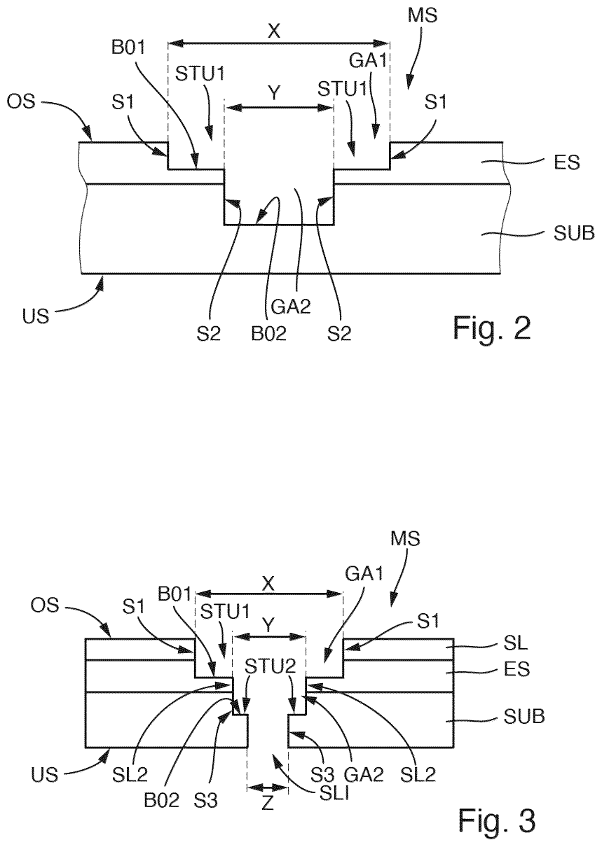

The illustration in FIG. 2 shows a cross-sectional view of the trench structure of the embodiment shown in FIG. 1c after a wet etching step and coating removal process. Only the differences from the illustration in FIG. 1c will be explained below.

A wet etching step is carried out to clean side walls S1, S2 and first step STU1 and second bottom surface BO2. Side surfaces S1 and S2 are set back; i.e., the width X of first trench GA1 and the width Y of the second trench are slightly increased. The depth of second trench GA2 is also slightly greater; i.e., second bottom surface GA2 BO2 is moved deeper into substrate SUB.

In order to protect upper side OS of the multi-junction solar cell MS from etching attack, the protective coating on upper side OS is only removed after the wet etching process by means of a coating removal process.

A cross-sectional view of the trench structure of the embodiment, shown in connection with the illustration in FIG. 1c, is shown in the illustration in FIG. 3 after a third processing step carried out by means of the laser. Only the differences from the illustration in FIG. 1c will be explained below.

In a third processing step, an opening with a width Z is created using the laser to form the slot SLI, wherein the opening in which the slot SLI is continuous (i.e., the slot SLI extends to the underside US) has no bottom surface and the width Z is smaller than the width Y. By creating a slot in only a part of second bottom surface BO2 of the epilayer system, a second step STU2 is created.

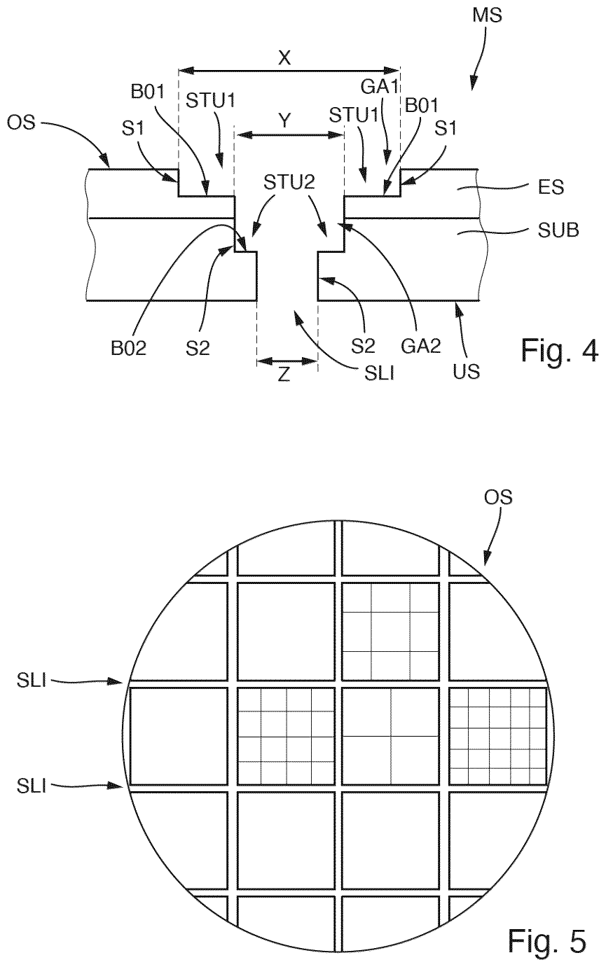

A cross-sectional view of the trench structure, shown in connection with the illustration in FIG. 2, is shown in the illustration of FIG. 4 after a slot has been created in the third processing step by means of a sawing step. Only the differences from the previous embodiment, shown in conjunction with the illustration in FIG. 2, will be explained below.

In a processing step, which is not shown, substrate SUB is thinned from underside US before the third processing step is carried out.

After the thinning of the semiconductor wafer, a slot SLI is created starting from the underside US of substrate SUB in a sawing step using a saw in order to divide the solar cell stacks MS formed on the front side.

The illustration in FIG. 5 shows a top plan view of a semiconductor wafer, wherein both the trench structure and the slot are formed on the semiconductor wafer.

Only the differences from the previous illustration in FIG. 2 will be described below. In the present embodiment, a slot is created along the trench structure in the third processing step. The slot always begins and ends at the edge of the semiconductor wafer.

On upper side OS of the multi-junction solar cell structure MS, both slot structures SLI and trench structures without slots are shown. One advantage is that both structures are formed on the same semiconductor wafer.

It turns out that different sizes of components can be produced on a semiconductor wafer.

The invention being thus described, it will be obvious that the same may be varied in many ways. Such variations are not to be regarded as a departure from the spirit and scope of the invention, and all such modifications as would be obvious to one skilled in the art are to be included within the scope of the following claims.

What is claimed is:

1. A method for producing a trench-shaped structure in a III-V multi-junction solar cell with an upper side and an underside, the III-V multi-junction solar cell comprises a substrate arranged on the underside, the substrate being formed as a semiconductor wafer and has an epilayer system with a plurality of III-V layers on a front side, the epilayer system comprises at least one first III-V solar cell formed on the upper side of the III-V multi-junction solar cell, and an organic layer is arranged on the first III-V solar cell, the method comprising:
forming, in a first processing step, a first trench with a width X and with a bottom surface in the epilayer system via a laser;
forming, in a second processing step, a second trench with a width Y and with a bottom surface in the substrate and is created in the bottom surface of the first trench via the laser, wherein the width Y is smaller than the width X, so that a first step is formed with the execution of the second processing step,
performing the first and second processing steps in a specified sequence or performing the second processing step before the first processing step and the second trench with the width Y is created before the first trench with the width X.

2. The method for producing a trench-shaped structure in a III-V multi-junction solar cell according to claim 1, wherein, in a third processing step, a slot is created in the bottom of the second trench along the trench-shaped structure starting from the upper side or starting from the underside via a separation process in order to divide the substrate.

3. The method for producing a trench-shaped structure in a III-V multi-junction solar cell according to claim 2, wherein, in the third processing step, the substrate is divided via a saw starting from the underside of the III-V multi-junction solar cell.

4. The method for producing a trench-shaped structure in a III-V multi-junction solar cell according to claim 2, wherein the third processing step is carried out using the laser starting from the upper side of the III-V multi-junction solar cell.

5. The method for producing a trench-shaped structure in a III-V multi-junction solar cell according to claim 1, wherein a wet etching step is carried out after the execution of all laser-based processing steps.

6. The method for producing a trench-shaped structure in a III-V multi-junction solar cell according to claim 1, wherein the organic layer is removed only after the execution of all laser-based processing steps and a wet etching step.

7. The method for producing a trench-shaped structure in a III-V multi-junction solar cell according to claim 1, wherein the substrate comprises Ge or GaAs or consists of Ge or GaAs.

8. The method for producing a trench-shaped structure in a III-V multi-junction solar cell according to claim 1, wherein further III-V layers are formed above the first Ill-V solar cell and below the organic layer.

9. The method for producing a trench-shaped structure in a III-V multi-junction solar cell according to claim 1, wherein the organic layer is formed as a continuous layer covering the entire upper side of the III-V multi-junction solar cell.

10. The method for producing a trench-shaped structure in a III-V multi-junction solar cell according to claim 1, wherein at least one III-V layer and/or at least one dielectric layer is formed between the first III-V solar cell and the organic layer.

11. The method for producing a trench-shaped structure in a III-V multi-junction solar cell according to claim 1, wherein an antireflection layer is formed between the first III-V solar cell and the organic layer.

12. The method for producing a trench-shaped structure in a III-V multi-junction solar cell according to claim 1, wherein a metal layer is arranged on the upper side of the III-V multi-junction solar cell before the first processing step in the area of the trench between the first III-V solar cell and the organic layer or no metal layer is formed.

13. The method for producing a trench-shaped structure in a III-V multi-junction solar cell according to claim 1, wherein the first trench extends exclusively along a straight line and/or a curvature and a first step or at least two steps or exactly two steps are formed along the extent of the first trench and the second trench via the laser-based processing steps.

14. The method for producing a trench-shaped structure in a III-V multi-junction solar cell according to claim 1, wherein the third processing step is not carried out in predetermined areas, so that the second bottom is retained and the substrate is not divided in the predetermined areas.
